(19) United States
(12) Patent Application Publication
(10) Pub. No.: US 2009/0275209 A1
(43) Pub. Date: Nov. 5, 2009

(54) PLASMA PROCESSING APPARATUS AND METHOD

(76) Inventors: Shinzo Uchiyama, Utsunomiya-shi (JP); Nobumasa Suzuki, Moriya-shi (JP); Hideo Kitagawa, Moriya-shi (JP); Yusuke Fukuchi, Tsukuba-shi (JP)

Correspondence Address: COWAN LIEBOWITZ & LATMAN P.C.;JOHN J TORRENTE, 1133 AVE OF THE AMERICAS, NEW YORK, NY, 10036, US

(21) Appl. No.: 12/139,902

(22) Filed: Jun. 16, 2008

Related U.S. Application Data
(62) Division of application No. 11/190,794, filed on Jul. 27, 2005, now abandoned.

(30) Foreign Application Priority Data
Jul. 28, 2004 (JP) 220210/2004

(51) Int. Cl. H01L 21/46; C23C 16/511

(52) U.S. Cl. 438/758; 118/723 MW; 257/E21.482

(57) ABSTRACT

Disclosed is a plasma processing apparatus and a plasma processing method, by which ions of plasma can be injected uniformly over the whole surface of a substrate to be processed, in a short time. Specifically, when the substrate is processed in a reaction container, the gas pressure inside the reaction container is increased. Alternatively, the distance between a plasma processing portion and the substrate is enlarged, or the substrate is temporally moved outwardly of the reaction container. As a further alternative, a shutter is disposed between the plasma producing zone and the substrate. With this procedure, incidence of ions of the plasma upon the substrate can be substantially intercepted for a predetermined time period from the start of plasma production.

### CROSS-REFERENCE TO RELATED APPLICATIONS

This application is a divisional of application Ser. No. 11/190,794, filed Jul. 27, 2005, the entire disclosure of which is hereby incorporated by reference.

### FIELD OF THE INVENTION AND RELATED ART

This invention related to plasma processing apparatus and method for injecting ions of plasma into a whole surface to be processed, uniformly and in a short time. Such apparatus and method will be particularly suitably usable in production of microdevices having an extraordinarily fine pattern, such as semiconductor chip (e.g. VLSI: very large scaled integrated circuit, LCD (liquid crystal display), CCD (charge coupled device), thin-film magnetic head, micromachine, etc.

### DESCRIPTION OF THE RELATED ART

In recent attempts to meet further increases in density of semiconductor devices, silicon oxynitride films are used as a gate insulating film of a thickness not greater than 3 nm. The silicon oxynitride film is produced by introducing nitrogen into a silicon oxide film. The silicon oxynitride film has high relative dielectric constant, and also it has a function for reducing leakage current or boron diffusion from a gate electrode. Because of these superior characteristics, the silicon oxynitride film is becoming an attractive material.

As regards the method of nitriding a silicon oxide film, a thermal process, a remote plasma process, and a microwave plasma process, for example, have been proposed.

The first method, i.e., a silicon oxynitride film forming method based on thermal processing, is that a wafer is heated for a few hours in a nitric monoxide gas ambience. This method is to thermally nitride the silicon oxide film.

In this method, however, the wafer is heated to a high temperature around 800 to 1000° C. and, thus, nitrogen easily moves inside the silicon oxide film and reaches the interface between the silicon oxide film and the silicon. Since there is a difference in respect to easiness of diffusion between the silicon oxide film and the silicon, nitrogen is accumulated at the interface between them. Hence, as regards a nitrogen concentration distribution in depth direction inside the silicon oxide film resulting from the thermal nitriding process, nitrogen is not localized at the surface while, on the other hand, the nitrogen concentration at the interface between the silicon and the silicon oxide film becomes high. Since the nitrogen concentration at the interface between silicon and silicon oxide film is high, the device characteristic will not be good. Further, because of high temperature treatment of a wafer at around 800 to 1000° C., substances other than nitrogen will be diffused together, and this will make the device characteristic worse. Furthermore, there is another problem that the process time is quite long.

The second method, i.e., a silicon oxynitride film forming method based on remote plasma processing, is that nitrogen ions in nitrogen plasma are sufficiently reduced and only nitrogen active species are conveyed to a wafer, to nitride a silicon oxide film. According to this method, while using nitrogen active species having high reactivity, a silicon oxide film can be nitrided at a relatively low temperature around 400° C. By keeping a reaction container at a high pressure or by separating a plasma producing zone and a wafer far away from each other, nitrogen ions inside the plasma are reduced so that only nitrogen active species can be used. Regarding the nitrogen concentration distribution in depth direction inside the silicon oxide film resulting from the remote plasma processing, it can be made larger at the surface and it can be made smaller at the interface between silicon and silicon oxide film.

According to the remote plasma processing method, however, since necessary nitrogen active species will be reduced together with nitrogen ions inside the plasma, it is not easy to obtain sufficient nitrogen active species and thus the processing time is very long. Furthermore, there is another problem that, since the nitrogen concentration distribution in depth direction inside the silicon oxide film decreases sharply with the depth, it is difficult to assure an increased nitrogen surface concentration.

The third method, i.e., a silicon oxynitride film forming method based on microwave plasma, is that nitrogen ions are injected into a silicon oxide film at a low injection energy not greater than 5 eV, thereby to nitride the silicon oxide film.

According to the silicon oxynitride film forming method using microwave plasma, as compared with the two methods described above, the microwave plasma is at a low electron temperature around a few eV and, therefore, the ion injection energy can be made not greater than 5 eV. As a result, nitrogen can be localized approximately in a 2-nm top surface layer of the silicon oxide film, while assuring a state that substantially no nitrogen is present at the interface between the silicon and the silicon oxide film. Furthermore, since the wafer is processed by high density plasma mainly composed of ions, the processing time can be shortened advantageously.

According to this plasma processing method, however, there is a possibility that, within a very little time till the localized plasma spreads over the whole surface of a dielectric material window, ions in that plasma locally nitrides the silicon oxide film to thereby degrade the nitrogen uniformness of the silicon oxide film. Furthermore, since the silicon oxide film is processed by high density plasma, the time required for producing a silicon oxynitride film of desired nitrogen concentration is short so that the little time described above can not be disregarded.

### SUMMARY OF THE INVENTION

It is accordingly an object of the present invention to provide a novel and improved plasma processing apparatus by which at least one of the inconveniences described above can be removed or reduced.

It is another object of the present invention to provide a novel and improved plasma processing method by which at least one of the inconveniences described above can be removed or reduced.

In accordance with an aspect of the present invention, there is provided a method of processing a substrate to be processed, in a reaction container by plasma, the improvements comprising substantially intercepting incidence of ions of the plasma upon the substrate, for a predetermined time period from start of production of the plasma.

Here, the term “predetermined time period” refers to the time after start of plasma production and till the plasma distribution is stabilized to a level that nitirding uniformness of a substrate to be processed is not degraded. This time can be determined by actual measurement and, for example, it is about 1-5 seconds. Also, the term “substantially intercepting” refers to that ion flux is reduced to about 1/10 or less of that during an actual processing operation.

The intercepting means may be one of pressure controlling means for increasing the gas pressure inside the reaction container for substantial ion interception, shutter means disposed between the plasma producing zone and the substrate to be processed, stage means for retracting the substrate to a position not to be irradiated with ions, and stage means for moving the substrate away from the plasma producing zone.

The pressure controlling means may increase the gas pressure inside the reaction container, for ion interception, to not less than five time higher than that during an actual processing operation and yet not lower than 100 Pa.

The plasma may preferably be microwave plasma. Particularly, microwave surface-wave plasma having producing-zone plasma density of approximately 10¹¹/cm³ or more will be effective. Since the microwave surface-wave plasma has a high density, if the amount of ions to be injected into the substrate to be processed should be reduced, the processing will be completed in a few seconds. However, with such short-time processing, local processing of the substrate by locally produced plasma can not be disregarded. Hence, in the case of high-density plasma such as microwave surface-wave plasma, in regard to the uniformness it is important to prevent only ions of the plasma, at its early stage of production, from being incident on the substrate to be processed.

In accordance with the present invention, during a period from start of plasma production to plasma stabilization, ions of the plasma are substantially prevented from being incident on the substrate to be processed. As a result, the whole surface of the substrate can be processed with uniform ion density. Thus, high-density plasma can be used, and ions of the plasma can be injected over the whole surface of the substrate uniformly and in a short time.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic and sectional view of a microwave surface-wave plasma processing apparatus according to a first embodiment of the present invention.

FIG. 2 is a graph for explaining the relation between ion density and distance from a dielectric material window.

FIG. 3 is a schematic and sectional view of a microwave surface-wave plasma processing apparatus according to a second embodiment of the present invention.

FIG. 4 is a sectional view taken along a line A-A′ in FIG. 3.

FIG. 5 is a schematic and sectional view of a microwave surface-wave plasma processing apparatus according to a third embodiment of the present invention.

FIG. 6 is a schematic and sectional view of a microwave surface-wave plasma processing apparatus according to a fourth embodiment of the present invention.

### DESCRIPTION OF THE PREFERRED EMBODIMENTS

Preferred embodiments of the present invention will now be described with reference to the attached drawings.

In accordance with the present invention, when a surface of a substrate to be processed is processed by plasma, only ions of the plasma at an early stage of production are substantially prevented from being incident on the substrate. By reducing ion flux, reaching to the substrate during plasma production, approximately to 1/10 or less of that during an actual processing operation, it is assured that the substrate is processed uniformly.

### First Embodiment

In accordance with a first embodiment of the present invention, the gas pressure in a reaction container is made not less than 10 times higher than that in an actual processing operation and yet not less then 100 Pa. Subsequently, plasma is produced, and only ions in the plasma locally produced are prevented from being incident on a substrate to be processed. After plasma discharging becomes stable, the gas pressure is lowered to allow an ion flux to impinge on the substrate, whereby plasma processing of the substrate is carried out.

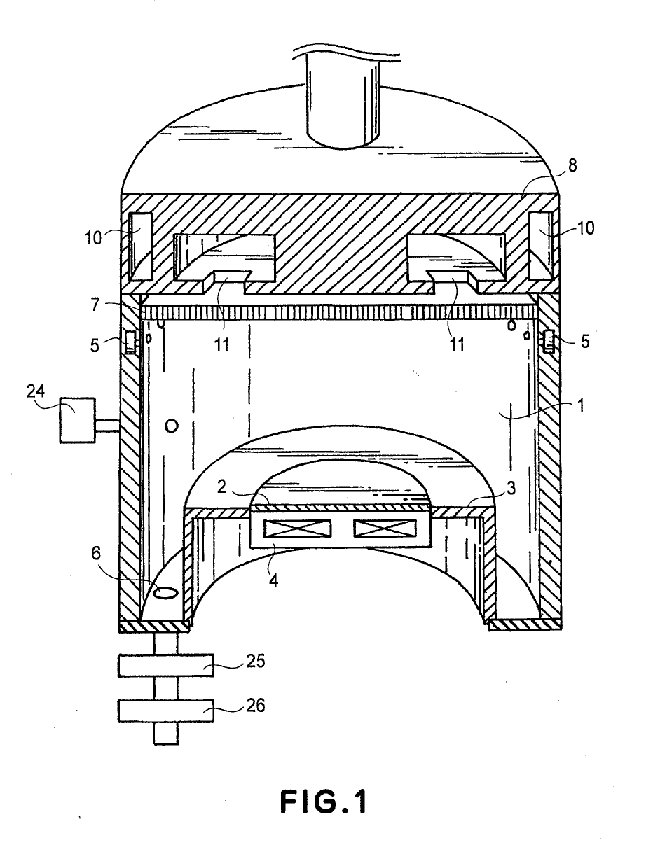

FIG. 1 illustrates a general structure of a microwave surface-wave plasma processing apparatus according to the first embodiment of the present invention. In FIG. 1, the apparatus comprises a plasma processing chamber 1, a substrate carrying table 3 for holding a substrate 2 thereon, a heater 4, a processing gas introducing means 5, an exhaust port 6, a slotted endless circular waveguide tube 8, slots 11 formed in the waveguide tube 8 at an interval corresponding to ½ or ¼ of the wavelength inside the microwave tube, a dielectric material window 7 for introducing microwaves into the plasma processing chamber 1, and a cooling water flowpassage 10 formed in the waveguide tube 8. The inner wall of the plasma processing chamber 1 and the dielectric material 7 are made of quartz, having no possibility of causing metal contamination of the substrate 2. The substrate table 3 is made of ceramics that contains aluminum nitride as a main component, while taking into account the metal contamination and thermal conduction of the heater 4. Denoted at 24 is a pressure detector for detecting the pressure inside the plasma processing chamber 1, and denoted at 25 is a pressure adjusting valve for adjusting the pressure inside the plasma processing chamber 1 on the basis of the opening of the valve. Denoted at 26 is a vacuum pump for evacuating the plasma processing chamber 1. The pressure detector 24 may be a commercially available detector such as Baratron Pressure Gauge available from MKS Instruments AG, and the pressure adjusting valve 25 may be a commercially available one such as Dry Pump available from Katayama Seisakusho Co.

In an early stage of plasma production and until locally produced plasma spreads over the whole surface of the dielectric material window 7, if the pressure inside the plasma processing chamber 1 is raised approximately over 130 Pa, ions in the locally produced plasma do not reach the substrate 2. Thus, local processing of the substrate 2 can be avoided.

On the other hand, after plasma discharging becomes stable, if the pressure inside the plasma processing chamber 1 is lowered to approximately below 130 Pa, ions in the plasma can reach the substrate 2, whereby the substrate 2 can be processed uniformly. Hence, the inside gas pressure of the reaction container is raised approximately over 130 Pa and, after that, plasma is produced. Subsequently, the gas pressure is lowered to approximately below 130 Pa. With this procedure, local ion injection to the substrate can be avoided and, thus, uniform ion density can be provided over the whole surface of the substrate to be processed.

In the microwave plasma processing, plasma is produced adjacent a dielectric material window that functions as a microwave introducing port. By diffusion from there, plasma is conveyed to a substrate to be processed and the substrate is processed thereby.

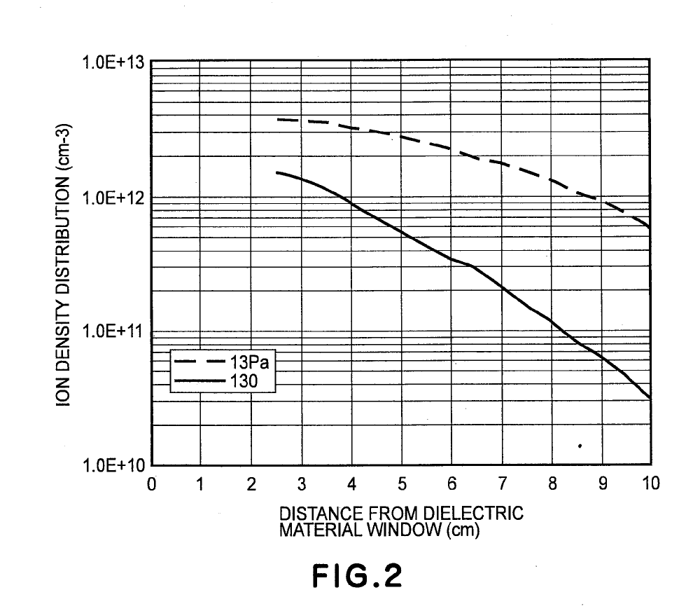

FIG. 2 illustrates an example of the relation between ion density and distance from a dielectric material window. It is seen in the drawing that, at a gas pressure approximately larger then 130 Pa, ions in the plasma are reduced rapidly with an increase of the distance from the plasma producing zone, due to recombination quenching with electrons or a decrease of diffusion length. At a distance of about 10 cm from the plasma producing zone near the dielectric material window, ions are reduced to about 1/100. Hence, by producing plasma after the gas pressure is raised to about 130 Pa, local processing of the substrate by locally produced plasma can be reduced and, even if the substrate s processed in a little time, sufficient uniformness is obtainable. Also, by subsequently decreasing the gas pressure to a desired pressure lower than approximately below the 130 Pa, ions of the plasma can be conveyed to the substrate, to be processed, efficiently without a large loss such that the substrate can be processed in a short time. Particularly, if the gas pressure is made lower than about 130 Pa, at a distance of about 10 cm from the plasma producing zone, ions in the plasma are reduced by only a fraction of those at the plasma producing zone and, therefore, the substrate can be processed quickly.

An example of plasma processing that uses the plasma processing apparatus of the first embodiment will be described later as a First Example.

### Second Embodiment

In accordance with a second embodiment of the present invention, a specific member is disposed between a plasma producing zone and a substrate to be processed, so as to substantially prevent plasma ions from being incident on the substrate. Subsequently, plasma is produced and, after the plasma discharging is stabilized, the above-described member is placed so that the ions of the plasma can be projected on the substrate. With this arrangement, only ions of plasma locally produced at an early stage of the plasma production are prevented from being incident on the substrate to be processed.

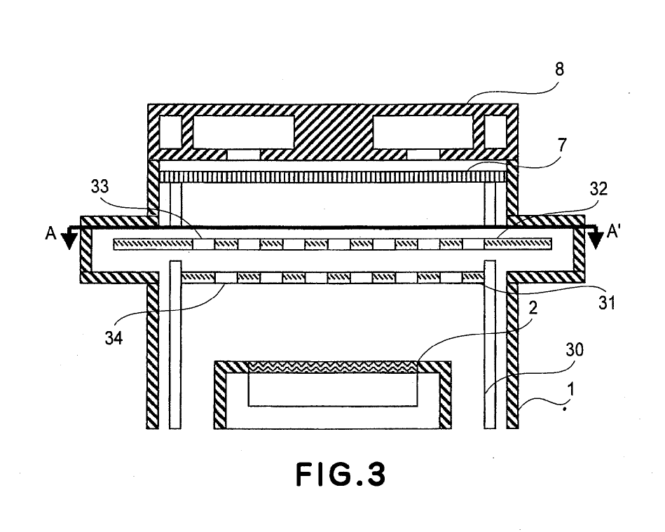

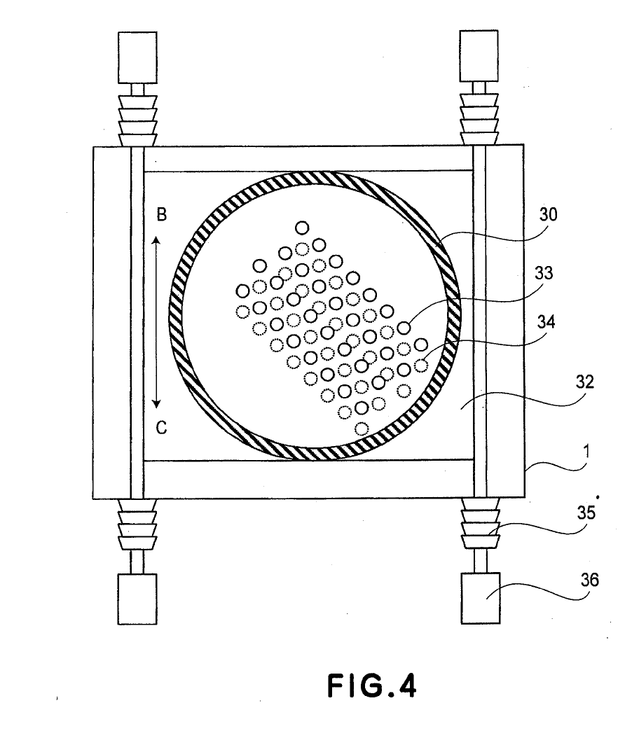

FIG. 3 illustrates a general structure of a microwave surface-wave plasma processing apparatus according to the second embodiment of the present invention. FIG. 4 is a sectional view taken along a line A-A′ in FIG. 3, for explaining a moveable quartz window mechanism of FIG. 3. In FIGS. 3 and 4, the plasma processing apparatus comprises a fixed quartz plate 31 having plural holes formed therein, a reciprocally movable quartz plate 32 having plural holes formed therein, a quartz cylindrical tube 30 for portioning between an operational portion of the movable quartz plate 32 and a substrate to be processed, holes 33 provided in the movable quartz plate 32, holes 34 provided in the fixed quartz plate 31, a bellows 35, and a linear motion device 36 such as a linear actuator, for example, for reciprocally moving the movable quartz plate 32, The linear motion device 36 is disposed at the atmosphere side. The components of this embodiment corresponding to those of the first embodiment are denoted by like numerals, and description therefore will be omitted.

The moveable quartz plate 32 takes a position B where the holes of the movable quartz plate 32 and the holes of the fixed quartz plate 31 are registered and the conductance becomes largest, and a position C where the holes of the movable quartz plate 32 and the holes of the fixed quartz plate 31 are mutually deviated and the conductance becomes smallest. By means of the linear motion device 36, the movable quartz plate 32 is reciprocally moved between these positions.

In the second embodiment, the procedure is as follows. First of all, by means of the linear motion device 36, the movable quartz plate 32 is placed at the position C. Subsequently, plasma is produced like the first embodiment. After the plasma is spread over the whole surface of the dielectric material window 7, the movable quartz plate 32 is moved to the position B.

By keeping the movable quartz plate 32 at the position C until locally produced plasma is spread over the whole surface of the dielectric material window 7, ions of the locally produced plasma are prevented from reaching the substrate 2 to be processed. Therefore, local processing of the substrate 2 can be avoided.

When the movable quartz plate 32 is placed at the position B, ions in the plasma can be diffused over the substrate 2, and thus the substrate 2 can be processed uniformly.

Hence, in accordance with this embodiment, a specific member is disposed between the plasma producing zone and the substrate to be processed so as to substantially prevent ions of the plasma from being incident on the substrate, and after that plasma is produced. After the plasma discharging is stabilized, the specific member is disposed to allow ions of the plasma to enter the substrate to be processed. With this arrangement, only ions of locally produced plasma are prevented from being incident on the substrate, and thus uniform ion density can be provided over the entire surface of the substrate.

### Third Embodiment

In accordance with a third embodiment of the present invention, plasma is produced inside a reaction container and, after the plasma discharging becomes stable, a substrate to be processed is conveyed into the reaction chamber. With this arrangement, only ions of locally produced plasma can be prevented from being incident on the substrate to be processed.

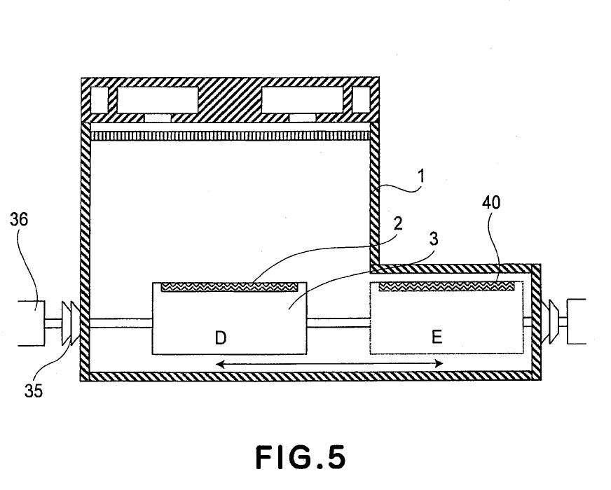

FIG. 5 illustrates a general structure of a microwave surface-wave plasma processing apparatus according to the third embodiment.

In the drawing, the plasma processing apparatus included a pre-chamber 40, a bellows 35, and a linear motion device 36 for reciprocally moving a substrate carrying table 3, The linear motion device 36 is provided at the atmosphere side. The components corresponding to those of the first embodiment are denoted by like numerals, and the description therefore will be omitted.

The substrate carrying table 3 is made reciprocally movable between a position D where the substrate 2 can be exposed to ions of plasma, and a position E inside the pre-chamber 40 where the substrate 2 is not easily exposed to the plasma ions. At the position E, the clearance between the pre-chamber and the top surface of the substrate carrying table 3 is a few millimeters to 1 cm, and this arrangement makes if difficult for plasma ions to impinge on the substrate 2 to be processed.

In the third embodiment, the procedure is as follows. First of all, by means of the linear motion device 36, the substrate carrying table 3 is placed at the position E. Subsequently, plasma is produced like the first embodiment. After the plasma is spread over the whole surface of the dielectric material window 7, the substrate carrying table 3 is moved to the position D.

By keeping the substrate carrying table 3 at the position E until locally produced plasma is spread over the whole surface of the dielectric material window 7, ions of the locally produced plasma are prevented from reaching the substrate 2 to be processed. Therefore, local processing of the substrate 2 can be avoided.

When the substrate carrying table 3 is placed at the position D, ions in the plasma can be diffused over the substrate 2, and thus the substrate 2 can be processed uniformly.

Hence, in accordance with this embodiment, after plasma is produced inside a reaction chamber, a substrate to be processed is conveyed into the reaction chamber. With this arrangement, only ions of locally produced plasma are prevented from being incident on the substrate, and thus uniform ion density can be provided over the entire surface of the substrate.

### Fourth Embodiment

In accordance with a fourth embodiment of the present invention, first a substrate to be processed and a plasma producing zone are spaced apart from each other and then plasma is produced. After the plasma discharging is stabilized, the substrate and the plasma producing zone are placed closer to each other. With this procedure, only ions of locally produced plasma are prevented from being incident on the substrate to be processed.

For example, with a gas pressure of 13 Pa and at a position spaced by about 20 cm from the plasma producing zone, ions of the plasma will be reduced to about 1/100, according to extrapolation based on the graph of FIG. 2. Hence, the substrate 2 is first separated from the plasma producing zone by about 20 cm and then plasma is produced. With this procedure, local processing by locally produced plasma can be reduced such that the substrate can be processed uniformly. Also, by subsequently moving the substrate toward the plasma producing zone to a distance under about 20 cm, ions of the plasma can be conveyed to the substrate efficiently without a large loss. Thus, the substrate can be processed in a short time. Particularly, if the substrate to be processed is placed at a distance of about 10 cm from the plasma producing zone, ions in the plasma will be reduced by only a fraction of those at the plasma producing zone and, therefore, the substrate can be processed quickly. If the gas pressure is raised, a similar effect is obtainable even with the distance between the plasma producing zone and the substrate is made shorter.

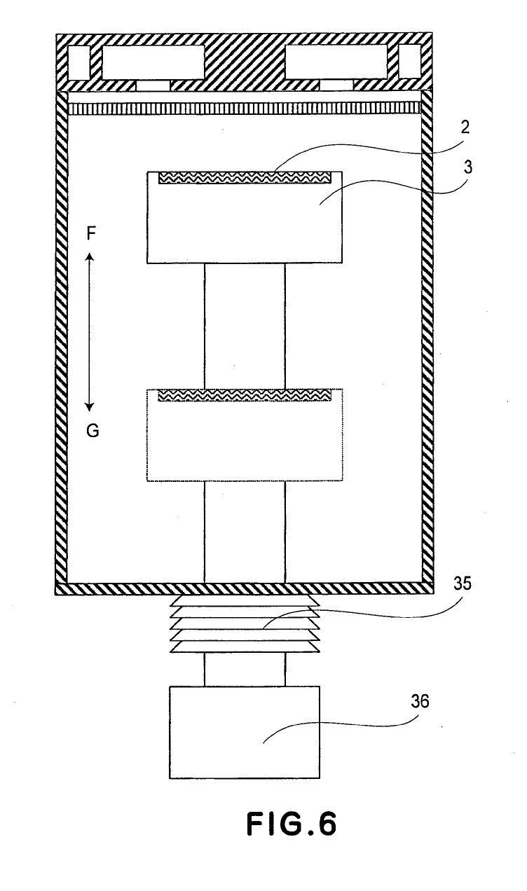

FIG. 6 illustrates a general structure of a microwave surface-wave plasma processing apparatus according to the fourth embodiment of the present invention.

In the drawing, the plasma processing apparatus includes a bellows 35 and a linear motion device 36 for moving a substrate carrying table upwardly and downwardly. The linear motion device 36 is disposed at the atmosphere side. The components of this embodiment are denoted by like numerals, and description therefore will be omitted.

The substrate carrying table 3 takes a position F which is approximately 10 cm from a dielectric material window 7 and a position G which is approximately 20 cm from the window 7, and be means of the linear motion device 36, the substrate carrying table 3 is made movable upwardly and downwardly between these positions. The processing pressure at that time may be 13 Pa.

At a gas pressure 13 Pa and at position G which is about 20 cm from the plasma producing zone, ions of the plasma will be reduced to about 1/100 or less, according to extrapolation based on the graph of FIG. 2. Furthermore, at the position F which is about 10 cm from the plasma producing zone, ions of the plasma will be reduced by only a fraction of that at the plasma producing zone. This means that the processing about at the position G will be an order of one-tenth, one-twentieth, etc. of that at position F.

By holding the substrate carrying table 3 at the position G until locally produced plasma is spread over the whole surface of the dielectric material window 7, the processing amount of the substrate 2 by the ions of locally produced plasma can be suppressed to a level of an order of one-tenth, one-twentieth, one-thirtieth, etc. of that at the position F.

Hence, in accordance with this embodiment, the substrate carrying table 3 is first placed at the position G and, after that, plasma is produced. Subsequently, the substrate carrying table is moved to the position F. With this procedure, the amount of local processing of the substrate 2 at the plasma production can be suppressed to a very low level of an order of one-tenth to one-hundredth, for example.

As described above, the plasma producing zone and the substrate to be processed are kept away from each other and, after that, plasma is produced. After the plasma discharging is stabilized, the plasma producing zone and the substrate are approximated to each other. With this procedure, only ions of locally produced plasma are prevented from being incident on the substrate, such that a uniform ion density can be provided over the whole surface of the substrate.

### Example 1

An example of plasma processing that uses the plasma processing apparatus shown in FIG. 1 will be explained below.

Cooling water flows through the cooling water flowpassage 10, to cool the endless circular waveguide tube 8 to a room temperature. While the inside pressure of the plasma processing chamber 1 is monitored by using the pressure detector 24, the vacuum pump 26 is operated and, by using the pressure adjusting valve 25, the inside pressure is adjusted to 0.1 Pa or lower. The substrate carrying table 3 is heated by the heater 4 to 200° C. A substrate 2 having a silicon oxide film of 2 nm formed on its surface is then conveyed to the substrate carrying table 3, and it is placed thereon. Subsequently, a nitrogen gas is introduced into the plasma processing chamber 1 through the processing gas introducing means 5, at a flow rate of 200 sccm. Then, by adjusting the pressure adjusting valve, the inside of the plasma processing chamber is held at 133 Pa. Microwaves of 1.5 kW is supplied from a microwave voltage source into the plasma processing chamber 1 through the endless circular waveguide tube 8 and the dielectric material 7, whereby plasma is produced inside the plasma processing chamber 1. The microwaves introduced into the endless circular waveguide tube 8 are bisected left and right, and they are introduced into the plasma processing chamber 1 from the slots 11 and through the dielectric material 7, whereby plasma is generated. This plasma is produced locally and then it is spread over the whole surface of the dielectric material window 7. Due to the presence of pressure 133 Pa, however, it is reduced rapidly as the distance from the dielectric material window 7 increases. At the surface of the substrate 2 which is at a distance 10 cm, the plasma becomes very weak almost as can be disregarded.

Subsequently, after elapse of 5 seconds, by using the pressure adjusting valve 25, the inside pressure of the plasma processing chamber is changed to 13 Pa. Furthermore, after elapse of 10 seconds, the microwave voltage source is interrupted, the supply of nitrogen gas is stopped, and the plasma processing chamber 1 is vacuum evacuated to a level of 0.1 Pa or lower. After this, the substrate 2 is conveyed out of the plasma processing chamber 1.

The nitrogen density distribution of the thus processed substrate was measured by using an optical film thickness gauge, and it was found that, as compared with a case where a substrate was processed by only 13 Pa, the uniformness was improved by about 20%.

As shown in the example of FIG. 2, at a pressure 130 Pa the nitrogen ions of the plasma decrease rapidly with an increase of the distance from the plasma producing zone. Also, at 13 Pa, they reduce gradually. Where the distance between the dielectric material window 7 and the substrate 2 to be processed is 10 cm, the ion density at 133 Pa is 5% of that at 13 Pa.

Hence, the inside gas pressure of the reaction container is first raised to about 130 Pa and then plasma is produced and, after that, the gas pressure is lowered to below 130 Pa. With this procedure, only ions of locally produced plasma are prevented from being incident on the substrate to be processed, such that a uniform nitrogen density can be provided over the whole surface of the substrate.

Although the embodiments and the example described above all concern a case wherein nitrogen is injected into a silicon oxide film, the present invention is not limited to use of nitrogen, but it is effectively applicable to use of hydrogen, oxygen, B, P, As and halogen, for example. Furthermore, the applicability of the present invention is not limited to a substrate having a silicon oxide film formed on its surface. The present invention is effectively applicable to injection to a substrate consisting of Si, Al, Ti, Zn, Ta, Bi, Sr, C, Zr, Ba, Yb, Pb, Mg, K, or Nb, for example, a substrate consisting of a compound including any one of these materials, or a substrate with an oxide film, a nitride film or a compound film of any one of these materials.

While the invention has been described with reference to the structures disclosed herein, it is not confined to the details set fourth and this application is intended to cover such modifications or changes as may come within the purposes of the improvements or the scope of the following claims.

This application claims priority from Japanese Patent Application No. 2004-220210 filed Jul. 28, 2004, for which is hereby incorporated by reference.

What is claimed is:

1. In an apparatus for processing a substrate to be processed, in a reaction container by plasma, the improvements comprising:
intercepting means for substantially intercepting incidence of ions of the plasma upon the substrate, for a predetermined time period from start of production of the plasma, wherein said intercepting means includes pressure controlling means for increasing a gas pressure inside said reaction container, for substantial interception of ions.

2. In an apparatus for processing a substrate to be processed, in a reaction container by plasma, the improvements comprising:
intercepting means for substantially intercepting incidence of ions of the plasma upon the substrate, for a predetermined time period from start of production of the plasma, wherein said intercepting means includes a shutter disposed between a plasma producing zone and the substrate, for substantial interception of ions.

3. In an apparatus for processing a substrate to be processed, in a reaction container by plasma, the improvements comprising:
intercepting means for substantially intercepting incidence of ions of the plasma upon the substrate, for a predetermined time period from start of production of the plasma, wherein said intercepting means includes a stage for retracting the substrate to a position not to be irradiated with ions, for substantial interception of ions.

4. In a method of processing a substrate to be processed, in a reaction container by plasma, the improvements comprising:
substantially intercepting incidence of ions of the plasma upon the substrate, for a predetermined time period from start of production of the plasma.
